(19) United States
(12) Patent Application Publication
(10) Pub. No.: US 2019/0251219 A1
(43) Pub. Date: Aug. 15, 2019

(54) CORRELATING VERIFICATION SCENARIO COVERAGE WITH HARDWARE COVERAGE EVENTS

(71) Applicant: International Business Machines Corporation, Armonk, NY (US)

(72) Inventors: JOERG BEHREND, RANGENDINGEN (DE); FRANZISKA GEISERT, ALTDORF (DE); HOLGER HORBACH, AIDLINGEN (DE); KLAUS KEUERLEBER, STUTTGART (DE); BERNHARD KICK, WALDENBUCH (DE); KARIN REBMANN, HOLZGERLINGEN (DE)

(21) Appl. No.: 15/896,318

(22) Filed: Feb. 14, 2018

(51) Int. Cl. G06F 17/50; G01R 31/317

(52) U.S. Cl. CPC G06F 17/5022; G06F 17/5045; G01R 31/31704

(57) ABSTRACT

Determining simulation test coverage for a design of an electronic circuit, where graph-based verification tools are used to verify functional correctness of said design. A test coverage is determined from specified coverage points, and hardware test coverage is measured based on the occurrence of selected events. A specification for simulation test scenarios, and a hardware design language specification for the design comprising hardware events are provided. A list of event groups belonging to one simulation test scenario is created. For each group a temporal property coverage checker in the simulation model is generated that comprises a switch to enable or disable it.

### BACKGROUND

The present disclosure relates to the field of verification, and more particularly relates to a method of correlating verification scenario coverage with hardware coverage events.

### SUMMARY

Various embodiments provide for a computer implemented method of controlling verification coverage of a chip design and a computer program product for controlling verification coverage of a chip design. Advantageous embodiments are described in the independent claims. Embodiments of the present disclosure can be freely combined with each other if they are not mutually exclusive.

In one aspect, the disclosure relates to a computer-implemented method of controlling verification coverage of a chip design, comprising: providing a hardware design language specification that is adapted to simulate a behavior of a chip design; providing a specification for simulation test scenarios that is adapted to run verification tests against an executable of the hardware design language specification; in the hardware design language specification identifying specific parts of the behavior to be tested; instrumenting the identified parts in the hardware design language specification; finding corresponding parts in the specification for simulation test scenarios; instrumenting the corresponding parts in the specification for simulation test scenarios to exert control on the execution of a program flow that is based on the instrumented hardware design language specification.

In another aspect, the disclosure relates to a computer program product for controlling verification coverage of a chip design, the computer program comprising: a computer readable storage medium having computer usable code embodied therewith, wherein the computer readable storage medium is not a transitory signal per se, the computer usable program code comprising: computer usable code configured for providing a hardware design language specification that is adapted to simulate a behavior of a chip design; computer usable code configured for providing a specification for simulation test scenarios that is adapted to run verification tests against an executable of the hardware design language specification; computer usable code configured for, in the hardware design language specification, identifying specific parts of the behavior to be tested; computer usable code configured for instrumenting the identified parts in the hardware design language specification; computer usable code configured for finding corresponding parts in the specification for simulation test scenarios; computer usable code configured for instrumenting the corresponding parts in the specification for simulation test scenarios to exert control on the execution of a program flow that is based on the instrumented hardware design language specification.

In another aspect, the disclosure relates to a system for controlling verification coverage of a chip design, the system being adapted for providing a hardware design language specification that is adapted to simulate a behavior of a chip design; providing a specification for simulation test scenarios that is adapted to run verification tests against an executable of the hardware design language specification; in the hardware design language specification identifying specific parts of the behavior to be tested; instrumenting the identified parts in the hardware design language specification; finding corresponding parts in the specification for simulation test scenarios; instrumenting the corresponding parts in the specification for simulation test scenarios to exert control on the execution of a program flow that is based on the instrumented hardware design language specification.

### BRIEF DESCRIPTION OF THE DRAWINGS

A detailed description of embodiments of the present disclosure is given in the following drawings in which:

FIG. 1 shows a block diagram of a computer processing system;

FIG. 2 shows a verification environment;

FIG. 3 shows an illustration of a method of verification of a hardware design;

FIG. 4 shows another illustration of a method of verification of a hardware design; and

FIG. 5 shows a flowchart of how to achieve the method shown in FIG. 4.

### DETAILED DESCRIPTION

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

The present method as described below may provide controlling verification coverage of a chip design, or a simulation test coverage of a chip design. This may have the benefit that it is ensured that all events that are expected to occur within a given test scenario occur therein.

The method may further comprise providing a hardware design language specification that is adapted to simulate a behavior of a chip design. This may have the benefit, that it is not necessary to have the chip in hardware, but that it is possible to simulate its behavior without incurring the high costs of hardware chip production, and, in good time before production, finding possible flaws in the chip design.

The method may further comprise providing a specification for simulation test scenarios that is adapted to run verification tests against an executable of the hardware design language specification.

The method may further comprise, in the hardware design language specification, identifying specific parts of the behavior to be tested. The identifying may be performed by an automatic parsing. A specific part of the behavior might be an event along with its associated commands. An event may be regarded as a situation where a logical level of a line changes. In chip simulation code, an event statement may be used to define what has to happen when the specified event occurs, whereas “what has to happen” is specified in related code.

The method may further comprise instrumenting the identified parts in the hardware design language specification. “Instrumenting” as used herein, in particular means providing specific parts of software with additional commands. This may have the benefit of better controlling which parts of an executable form of the hardware design language specification shall be executed.

The method may further comprise finding parts in the specification for simulation test scenarios that correspond to the above identified parts in the hardware design language specification. This may have the benefit that a relation is established between the hardware events and its corresponding test scenarios.

The method may further comprise instrumenting the corresponding parts in the specification for simulation test scenarios to exert control on, e.g. the behavior of, the execution of a program flow that is based on the instrumented hardware design language specification.

As used herein, “hardware design language specification” refers to a hardware description in a high level language, such as HDL or VHDL. Such hardware design language specification may comprise a hardware event and corresponding commands that are to be executed by the designed chip or signals that are to be issued by the designed chip. For example, a hardware event might be a clock event and the corresponding commands might comprise incrementing a counter, and issuing a signal if the counter value indicates a lapse of, e.g., an hour. In particular, “hardware design language specification” does not mean a specification of some hardware design language, but merely a specification written in a hardware design language.

For execution, a hardware design language specification or an instrumented derivative thereof may be compiled and linked to form an executable program, that is able to simulated the behavior of the designed chip. Such executable program based in one or another form on the hardware design language specification may be referred to as “hardware simulation” or “hardware simulator” or, in some specific cases, as “hardware”.

As used herein, “specification for simulation test scenarios” refers to a software specification, that may be written in a higher level language, to send stimuli towards the hardware simulation, the stimuli being organized in test scenarios. The specification for simulation test scenarios may further comprise code to check the response issued by the hardware simulation having received the stimulus. The “specification for simulation test scenarios” may also be referred to as “verification software”. In particular, the specification for simulating test scenario—when in executable form—may be adapted to communicate with the simulation software.

According to some embodiments, instrumenting the identified parts in the simulation software may comprise providing a toggle that is adapted to switch on or off execution flow of the simulation software for the specific part of behavior. This may have the benefit that the toggle switches on the execution flow when, from the side of the specification for simulation test scenarios, driving through some specific events in the simulation is deemed necessary, and, switching the execution flow through that event off, when the corresponding test is not deemed necessary. Thus, the toggle may also be referred to as enabling or disabling a temporal property coverage checker.

According to one embodiment, instrumenting the corresponding parts in the specification for simulation test scenarios comprises providing a control part therein that is adapted to control a toggle in the hardware design language specification.

According to one embodiment, the hardware design language specification is adapted to specify the behavior of the chip on a register transfer level. As used herein, “register transfer level” refers to a specific level of a design abstraction of a chip design.

According to one embodiment, the hardware design language specification comprises hardware events, wherein a hardware event is assigned to a simulation test scenario.

According to one embodiment, creating a list of event groups from said hardware design language specification is comprised, wherein the events in a respective group belong to a same simulation test scenario.

According to one embodiment, comprised is, for each event from a list of event groups generating, in the specification for simulation test scenarios, a temporal property coverage checker comprising a switch to enable or disable it.

According to one embodiment, comprised is, for each simulation test scenario, instrumenting the hardware design language specification by generating means therein to control a toggle associated with the said simulation test scenario such that a respective coverage checker is enabled when the scenario is entered and is disabled when the scenario has passed.

According to one embodiment, a graph-based verification tool is used to verify functional correctness of said chip design. This may be achieved using logic simulation.

According to one embodiment, the verification coverage of the specification for simulation test scenarios is determined from specified coverage points based on a graph path specification.

As used herein, a coverage point may be identified with an event and the command sequence triggered when the event occurs.

As used herein, a graph path specification may be an alternative term for control flow graph.

According to one embodiment, a hardware test coverage is determined based on the occurrence of selected events.

According to one embodiment, the steps of instrumenting the identified parts in the hardware design language specification, finding corresponding parts in the specification for simulation test scenarios, and instrumenting the corresponding parts in the specification for simulation test scenarios are performed automatically.

According to one embodiment, comprised is automatically assessing, as to whether or not a coverage is achieved.

According to one embodiment, the hardware design language specification is written in a high level language.

The present disclosure may be a system, a method, and/or a computer program product. The computer program product may include a computer readable storage medium (or media) having computer readable program instructions thereon for causing a processor to carry out aspects of the present disclosure.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present disclosure may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present disclosure.

Aspects of the present disclosure are described herein with reference to flowchart illustrations and/or block diagrams of methods, apparatus (systems), and computer program products according to embodiments of the disclosure. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present disclosure. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

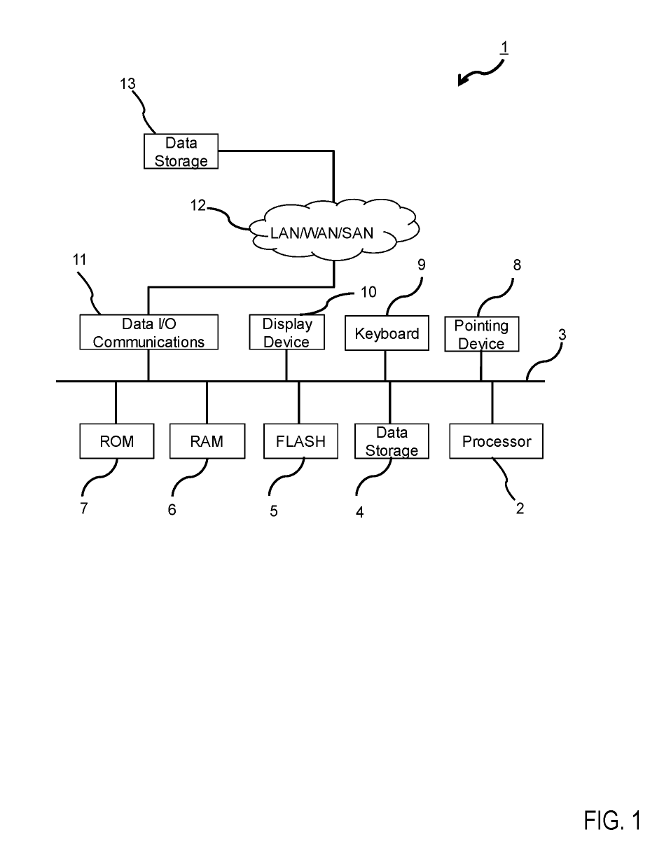

A block diagram illustrating an example computer processing system adapted to implement the methods of the present disclosure is shown in FIG. 1. The computer system, generally referenced 1, comprises a processor 2 which may comprise a digital signal processor (DSP), central processing unit (CPU), microcontroller, microprocessor, microcomputer, ASIC or FPGA core. The system also comprises static read only memory 7 and dynamic main memory 6 and may also comprise a FLASH memory 5. The processor 2 is via a bus 3 in communication with any of said memory devices as well as with peripheral devices such as a display device 10, a keyboard 9, a pointing device 8, such as, e.g., a mouse or a tablet.

The computer system is connected to one or more external networks such as a LAN or WAN or SAN 12 via communications lines connected to the system via one or more data I/O communication interfaces 11, e.g. a network interface 11. The network adapters 11 coupled to the system enable the data processing system to become coupled to other data processing systems or remote printers or storage devices through intervening public or private networks. Modem, cable modem and Ethernet cards are just a few of the currently available types of network adapters. The system comprises also a magnetic or semiconductor based data storage or storage device 4 and/or 13 for storing application programs and data. The system comprises computer readable storage medium that may include any suitable memory means, including but not limited to, magnetic storage, optical storage, semiconductor volatile or non-volatile memory or any other memory storage device.

Verifying that a hardware design of a semiconductor chip functions properly is of utmost importance, because, if an error in design is not found before producing the hardware, high costs may arise to the manufacturer. To achieve this, a conventional verification environment for testing the correctness of a circuit design by simulation typically includes, among other verification components, checker to verify that signals of the design behave as expected, relative to themselves and relative to other signals. These checkers report an error each time they detect that an output signal outputted by the simulator of the design under test (DUT) is not identical to the expected output signal that is implemented in the verification software.

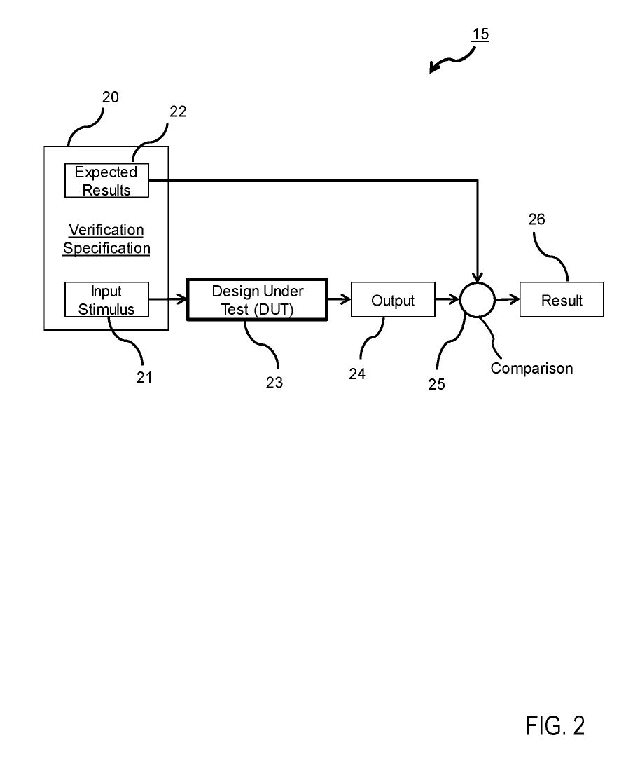

In FIG. 2, an exemplary verification environment 15 is depicted: A verification specification 20, that might be written in a high level programming language such as C++ or Verilog that is specific for verifying a DUT 23, comprises software parts 21 issuing input stimuli, i.e. predefined signals, towards the DUT 23, that might be a simulator of the hardware design. The DUT 23, based on the input signals or input stimulus 21, calculates an output 24 that is forwarded to a comparison component 25. The comparison component 25 compares the outputted result 24 from the DUT 23 to one or more expected result(s) 22 that are also specified in the verification specification 22. In computer language, this apparent complicate process might mainly be implemented, e.g., by a simple assert-statement. A result 26 of the verification gives an information as to whether or not the DUT 23 exhibited the expected behavior. The DUT might be simulated, e.g. in a hardware description language, as for example, HDL or VHDL, that are known to the skilled person.

In the following, the verification software simulating stimuli towards the DUT may also be referred to as “simulation”, whereas the DUT, that is a hardware simulation, may in the following be referred to as “hardware”. From the context, bearing the aforementioned in mind, the respective meanings will be always clear for the skilled person.

As verification components are usually written in a high level language like C++ or Verilog, the retrieving of values from the simulated hardware can therefore usually be tracked down to a small number function calls (like getValue( )) that interact directly between the verification code and the hardware simulator. The checks itself are then based on a number of calculations and endup in a boolean expression that is followed by code reporting an unexpected behavior, i.e. an error.

In one exemplary embodiment, a computer-implemented method for controlling verification coverage of a chip design and/or of determining simulation test coverage may be suggested for a register transfer level design of an electronic circuit, wherein graph-based verification tools may be used to verify functional correctness of said design using logic simulation. Test coverage for said tools may be determined from specified coverage points based on graph path specifications. A hardware test coverage may be measured based on the occurrence of selected events. Such method may comprise one or more of the following: providing a specification for simulation test scenarios; providing a hardware design language specification for said design comprising hardware events, wherein a hardware event is assigned to a simulation test scenario; creating a list of event groups from said hardware design language specification, wherein the events in a group belong to the same simulation test scenario; for each group generating in the simulation model a temporal property coverage checker comprising a switch to enable or disable it; for each simulation test scenario generating means to control the corresponding switch in the simulation model such that the respective coverage checker is enabled when the scenario is entered and disabled when it after the check has passed.

In other words: Determining simulation test coverage for a design of an electronic circuit, wherein graph-based verification tools may be used to verify functional correctness of said design. A test coverage may be determined from specified coverage points, and hardware test coverage may be measured based on the occurrence of selected events. A specification for simulation test scenarios, and a hardware design language specification for the design comprising hardware events may be provided. A list of event groups belonging to one simulation test scenario may be created. For each group a temporal property coverage checker in the simulation model may be generated that comprises a switch to enable or disable it.

Thus, a method is suggested for determining simulation test coverage for a register transfer level design of an electronic circuit.

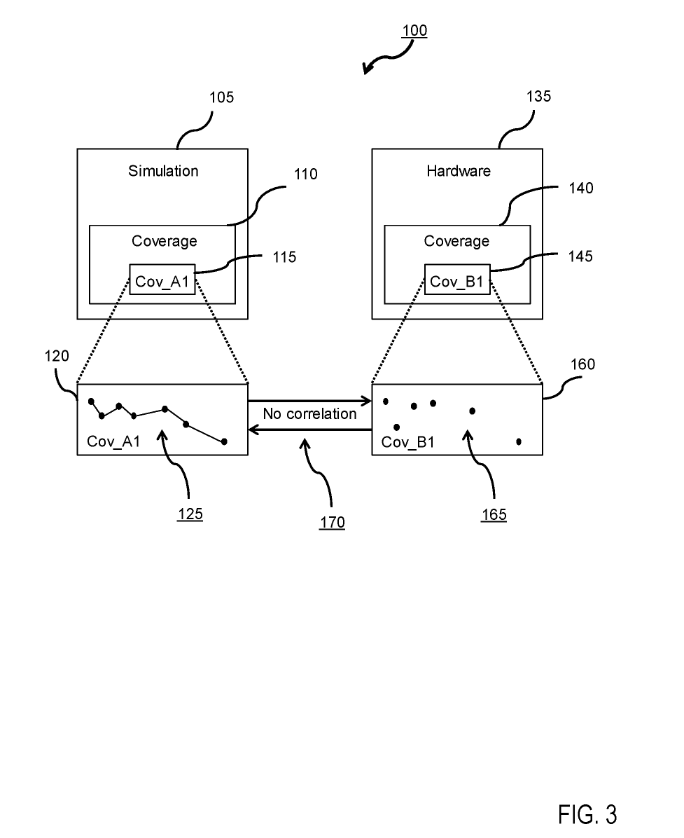

FIG. 3 is an illustration of a flowchart of a method 100 of performing simulation tests on a hardware. On the left hand side, simulation verification software 105 may provide a specific coverage 110 of a couple of test cases 115. The test cases 115 may be grouped to form a scenario Cov_A1. Enlarged in rectangle 120 is the same coverage 125. Cov_A1 thus may provide a path specification.

On the right hand side of FIG. 3, a hardware simulation 135 is depicted having its own coverage 140 of a couple of hardware events 145 to be tested. The hardware events may be grouped and summarized as Cov_B1. Rectangle 160 illustrates an enlarged view of the hardware events 165. Cov_B1 thus may provide cover points, as understood by a skilled person.

It is to be noted that there is no correlation, 170, between the simulation test cases and the hardware events. The hardware simulator may be written in VHDL, whereas the coverage may be graph based, and employing a software-coverage metrics is considered.

Coverage according to a setting of the diagram of FIG. 3 is measured separately for simulation and hardware. Because of this separation, a correlation between simulation and hardware is not feasible and, thus, is not performed.

Coverage metrics used differ from each other: In the hardware, coverage metrics measures special events in the hardware without knowledge about sanity, i.e., no context check is done with the driven testcase scenario. Contrarily, in the simulation and/or graph, coverage is measured based on specific coverage points in the verification code, based on path specification.

There is no indication of coverage points which shall not be hit by a planned scenario. This means: if simulation runs unexpected or wrong scenarios, because of, e.g., a wrong implementation, the hardware will count the coverage and will not return an error. Another risk is, when “clear” specified scenarios are executed on the simulation side, the hardware might run into wrong statespaces without obviously showing wrong behavior. The simulation side shows increasing coverage, whereas on the hardware side there is to be seen more coverage than expected but without having knowledge about it.

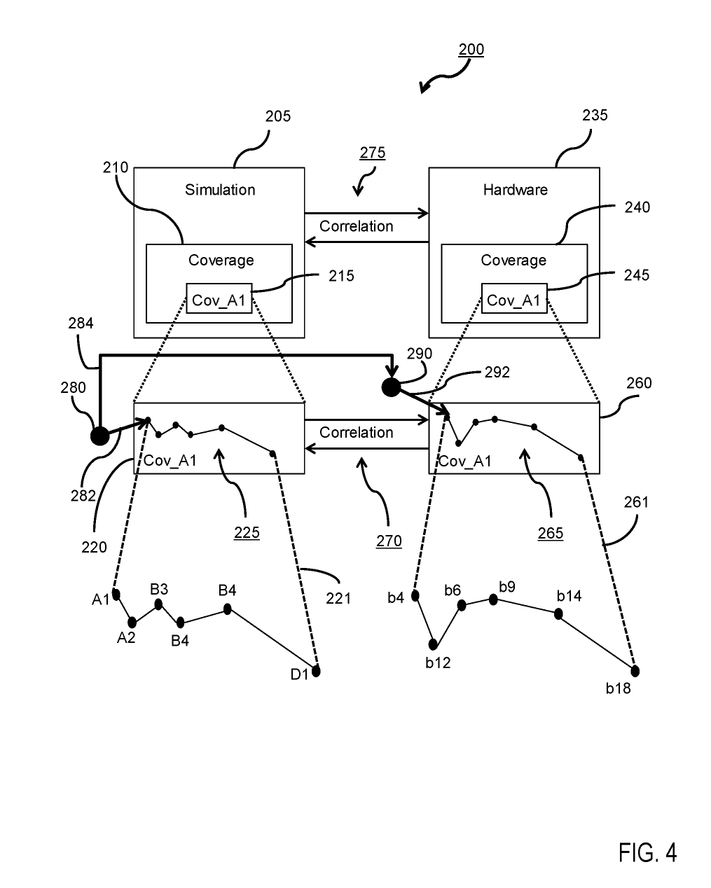

Now turning to FIG. 4, a modified flowchart of FIG. 3, is shown.

In a method 200, being considerable distinct from method 100, a simulation software 205 may provide a specific coverage 210 of a couple of test cases 215, that might be embodied as, e.g., graph or code. The test cases 215 may be grouped to form a scenario Cov_A1. Enlarged in rectangle 220 is the same coverage 225. A further enlargement is done as depicted by dashed line 221. As can be seen, a simulation test scenario might be given by a sequence specification as for, e.g., A1-A2-B3-B4-D1.

On the right hand side of FIG. 4, a hardware simulation is depicted having a coverage 240, that might be provided in VHDL or a similar hardware description language—the coverage 240 being associated with a couple of hardware events 245 to be tested. Rectangle 260 is an enlarged view of coverage Cov_A1, 245, of the hardware simulation under test. Dashed line 261 leads to a further enlarged view of the events under test, here, as an example, in a sequence b4-b12-b6-b9-b14-b18.

It is to be noted that all the test cases, both the simulator test cases as the hardware tests run under one and the same coverage Cov_A1. The reason therefore is that all the tests are correlated, as is illustrated by double arrows 270 and 275.

The correlation may be achieved technically both before runtime, when arming the hardware design language specification and the specification for simulating test scenarios, as well as during runtime, by having a starting point 280, that triggers, at 282, the execution of the test cases beginning with A1, and, at the same time, triggers, when coverage may be enabled, or set “on”, in 290, at 292, so that b4 is started.

In design time, that is when writing the verification, the correlation is founded, starting from the hardware events: The hardware events may be retrieved in the hardware description. The information gained therefrom may then be employed for adapting the test cases of the simulation.

In detail: First checker and coverage events will have to be specified as sequences in the hardware VHDL. This can be realized, e.g., by using a description language such as PSL or sugar, as is known by the skilled person.

When a simulation scenario is selected—which would mean, in a graph based simulation, that a goal and/or node is selected—then also the defined coverage sequence may get a start trigger event. Subsequently, all connected coverage events may be processed. The solution described herein can also be used for cover events by checking the expected incrementation of their counters.

Any unused coverage sequence in the hardware may be disabled by the trigger so that its corresponding events might not be hit. Otherwise, an error may be thrown.

A full random simulation is considered. To achieve this, the coverage sequence must be tied to deeper goals. The deeper the coverage sequence will be tied in the graph structure, the more exact the coverage correlation will be. In a full random simulation, the coverage sequence could also be pulled apart so that different coverage sequence parts may be connected to different goals.

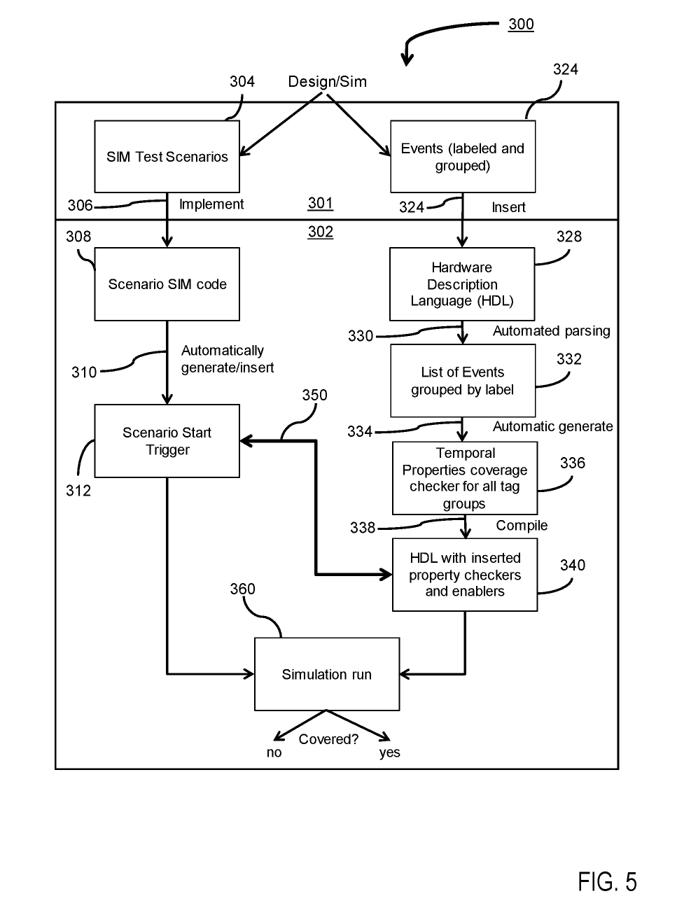

FIG. 5 depicts a flow chart 300 for achieving the correlation of the simulation side and the hardware side in the coding phase of the test.

Prescribed by design and/or simulation test scenarios 304 are defined in rectangle 301 that comprises only manual activities. Test scenarios 304 may be implemented, 306, to gain a scenario simulation code 308.

Concerning the hardware side, events, labeled and grouped, 324, are defined and inserted, 324, in files of a hardware description language, 328. By automated parsing, 330, the hardware description language file 328, a list 332 of hardware events grouped by label may be obtained. From the list 332 of hardware events there may be automatically generated, 334, temporal properties coverage checker for all tag groups, 336.

Upon compiling, 338, the temporal properties coverage checker for all tag groups, 336, to obtain HDL with inserted property checkers and enablers, 340, and automatically generating/inserting, 310, specific parts of scenario SIM code, 308, into scenario start trigger, 312, under correlating action 350, correlated simulation code, i.e. specification for simulation test scenarios, and hardware related code, i.e. hardware design language specification, may be generated, 312 and 340. The skilled person will understand that, as used herein, “generating” may also comprise “building a derivative of” or “building, by adding code, a derivative of”.

Upon starting a simulation run 360, and evaluating the obtained results, an assessment as to whether the testcases/events are covered or not may be performed resulting into one outcome of “yes” or “no”.

In other words, the prerequisites being described in rectangle 301, manual labeling of hardware events in the HDL may be performed. Also simulation test scenarios for each hardware coverage group may be written.

In the automatic processing, 302, on the hardware side, the list of tagged events may be automatically parsed out of the HDL file. For this purpose, standard tools like yacc/lex customized for this task may be used. When the complete list of the labeled events is obtained, temporal property coverage checkers for all groups may be generated, e.g., based on PSL. One event may be part of an arbitrary number of coverage groups. This task may be executed by a parsing process that takes the groups of all labels into account. There may be generated one property, e.g. PSL, per group. There may also be added automatically an enable (disable switch for each property, which switch may be used from the sim side to control the coverage checkers. These switches, e.g., hardware facilities, may be activated from simulation side, i.e. from the side of the specification for simulation test scenarios or derivatives thereof.

In the automatic processing, 302, on the simulation side, the group names from the hardware may be used in the simulation code to implement the corresponding scenarios for each coverage group. There may be automatically inserted into each scenario the corresponding enable/disable switch from the hardware. This may be done by using, e.g., a driver which sticks the simulation-only facilities in the hardware step (per group). When a specific scenario is entered, the corresponding coverage checker of this group may be enabled. After the check has passed, the coverage checker may be disabled again.

By connecting the simulation scenarios to the hardware coverage, a correlation between both the simulation side with the hardware side may be achieved that is not possible in a method as described in FIG. 3. According the latter, it is not possible to ensure that the coverage results directly correlate to the specific test scenario. Since, according that configuration, there was only a counter value for each individual coverage event, it was not possible to gain knowledge about which scenarios were originally triggering this event.

In the method as described with respect to FIGS. 4 and 5, it is possible to have sanity checks, e.g., checks as to whether the chip design works as expected as described above, as specified of the hardware coverage events for each running test case. Based thereon, it may be possible to get direct feedback during each testcase run whether the expected coverage has been hit or not. As a result, misunderstanding about hardware behavior between a verification engineer and the designer may be identified and resolved. In addition, implementation errors in hardware and simulation may be identified quickly and, thus, may be fixed, more quickly. Also the error prone review and sign-off process of test scenarios and coverage between simulation and design may be structured in the present method. Thus, it is clear as to whether a test scenario is implemented and can be signed-off or not. To summarize, the method suggested herein may make debugging a lot more efficient and may save a lot of time and money.

The suggested method according FIGS. 4 and 5 has several effects: Hardware and simulation coverage are strongly correlated, a sanity check of the hardware coverage events is possible, a misunderstanding about a hardware behavior between a verification engineer and a designer can be identified, and implementation errors in hardware and simulation can be identified.

The terminology used herein is for the purpose of describing particular embodiments only and is not intended to be limiting of the disclosure. As used herein, the singular forms “a”, “an”, and “the” are intended to include the plural forms as well, unless the context clearly indicates otherwise. It will be further understood that the terms “comprises” and/or “comprising”, when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the form disclosed. As numerous modifications and changes will readily occur to those skilled in the art, it is intended that the disclosure not be limited to the limited number of embodiments described herein. Accordingly, it will be appreciated that all suitable variations, modifications and equivalents may be resorted to, falling within the spirit and scope of the present disclosure. The embodiments were chosen and described in order to best explain the principles of the disclosure and the practical application, and to enable others of ordinary skill in the art to understand the disclosure for various embodiments with various modifications as are suited to the particular use contemplated.

What is claimed is:

1. A computer implemented method of controlling verification coverage of a chip design, comprising:
providing a hardware design language specification that is adapted to simulate a behavior of a chip design;
providing a specification for simulation test scenarios that is adapted to run verification tests against an executable of the hardware design language specification;
in the hardware design language specification, identifying specific parts of the behavior to be tested;
instrumenting the identified parts in the hardware design language specification;
finding corresponding parts in the specification for simulation test scenarios; and
instrumenting the corresponding parts in the specification for simulation test scenarios to exert control on the execution of a program flow that is based on the instrumented hardware design language specification.

2. The method of claim 1, wherein instrumenting the identified parts in the simulation software comprises providing a toggle that is adapted to switch on or off execution flow of the simulation software for the specific part of behavior.

3. The method of claim 1, wherein instrumenting the corresponding parts in the specification for simulation test scenarios comprises providing a control part therein that is adapted to control a toggle in the hardware design language specification.

4. The method of claim 1, wherein the hardware design language specification is adapted to specify the behavior of the chip on a register transfer level.

5. The method of claim 1, wherein the hardware design language specification comprises hardware events, wherein a hardware event is assigned to a simulation test scenario.

6. The method of claim 1, comprising creating a list of event groups from said hardware design language specification, wherein the events in a respective group belong to a same simulation test scenario.

7. The method of claim 1, comprising, for each event from a list of event groups, generating in the specification for simulation test scenarios a temporal property coverage checker comprising a switch to enable or disable it.

8. The method of claim 1, comprising, for each simulation test scenario, instrumenting the hardware design language specification by generating means therein to control a toggle associated with the said simulation test scenario such that a respective coverage checker is enabled when the scenario is entered and is disabled when the scenario has passed.

9. The method of claim 1, wherein a graph-based verification tool is used to verify functional correctness of said chip design

10. The method of claim 1, wherein the verification coverage of the specification for simulation test scenarios is determined from specified coverage points based on a graph path specification.

11. The method of claim 1, wherein a hardware test coverage is determined based on the occurrence of selected events.

12. The method of claim 1, wherein the steps of instrumenting the identified parts in the hardware design language specification, finding corresponding parts in the specification for simulation test scenarios, and instrumenting the corresponding parts in the specification for simulation test scenarios are performed automatically.

13. The method of claim 1, comprising automatically assessing, as to whether or not a coverage is achieved.

14. The method of claim 1, wherein the hardware design language specification is written in a high level language.

15. A computer program product for controlling verification coverage of a chip design, the computer program comprising:
a computer readable storage medium having computer usable code embodied therewith, the computer usable program code comprising:
computer usable code configured for providing a hardware design language specification that is adapted to simulate a behavior of a chip design;
computer usable code configured for providing a specification for simulation test scenarios that is adapted to run verification tests against an executable of the hardware design language specification;
computer usable code configured for, in the hardware design language specification, identifying specific parts of the behavior to be tested;
computer usable code configured for instrumenting the identified parts in the hardware design language specification;
computer usable code configured for finding corresponding parts in the specification for simulation test scenarios; and
computer usable code configured for instrumenting the corresponding parts in the specification for simulation test scenarios to exert control on the execution of a program flow that is based on the instrumented hardware design language specification.

16. A system for controlling verification coverage of a chip design, the system being adapted for:
providing a hardware design language specification that is adapted to simulate a behavior of a chip design;
providing a specification for simulation test scenarios that is adapted to run verification tests against an executable of the hardware design language specification;
in the hardware design language specification, identifying specific parts of the behavior to be tested;
instrumenting the identified parts in the hardware design language specification;
finding corresponding parts in the specification for simulation test scenarios; and
instrumenting the corresponding parts in the specification for simulation test scenarios to exert control on the execution of a program flow that is based on the instrumented hardware design language specification.
